(19) United States
(12) Patent Application Publication
(10) Pub. No.: US 2007/0066012 A1
(43) Pub. Date: Mar. 22, 2007

(54) Semiconductor device and method for fabricating the same

(76) Inventors: Takashi Ohtsuka, Toyama (JP); Takashi Nakabayashi, Toyama (JP)

Correspondence Address: MCDERMOTT WILL & EMERY LLP, 600 13TH STREET, N.W., WASHINGTON, DC, 20005-3096, US

(21) Appl. No.: 11/437,720

(22) Filed: May 22, 2006

(30) Foreign Application Priority Data
Sep. 16, 2005 (JP) 2005-269648

(51) Int. Cl. H01L 21/8242

(52) U.S. Cl. 438/250

(57) ABSTRACT

A semiconductor device comprises a capacitor formed by sequentially stacking a lower electrode, a capacitor insulating film, and an upper electrode over a substrate. The capacitor insulating film is made of Hf oxide or Zr oxide, and between the lower electrode and the capacitor insulating film, a first barrier film is formed which is made of Hf oxide or Zr oxide containing at least either of Al and Si.

### BACKGROUND OF THE INVENTION

(a) Fields of the Invention

The present invention relates to semiconductor devices and methods for fabricating the devices, and in particular to semiconductor devices with capacitors and methods for fabricating the devices.

(b) Description of Related Art

In recent years, semiconductor integrated circuit devices have had higher packing densities, more enhanced functionalities, and faster processing speed. With such a trend, a technique is proposed in which semiconductor devices such as DRAMs (Dynamic Random Access Memories) employ MIM (Metal-Insulator-Metal) capacitors having high dielectric films used as capacitor insulating films.

In order to provide a semiconductor device with a higher packing density and a more enhanced functionality, it is absolutely required to shrink the area occupied by a capacitor in a chip. However, the capacitor requires a capacitance of a certain value or higher to ensure a stable operation of a memory unit of the device. From these requirements, a capacitor using Hf oxide (HfOₓ) or Zr oxide (ZrOₓ) with a high dielectric constant for a capacitor insulating film has been under development.

The capacitor using HfOₓ or ZrOₓ for a capacitor insulating film, however, has the problem that leakage current increases with increasing operating temperature. This is because due to a low band gap of HfOₓ and ZrOₓ with respect to electrodes, the higher the temperature is, the more leakage current resulting from heat emission of electrons from the electrodes flows.

To avoid this problem, the following technique is proposed (see Japanese Unexamined Patent Publication No. 2002-222934). A barrier film of Al oxide (AlOₓ) with a high band gap is formed at the interface between an electrode and a capacitor insulating film of HfOₓ or ZrOₓ. Thereby, the band gap between the electrode and the capacitor insulating film is widened to suppress leakage current resulting from heat emission of electrons from the electrodes.

FIGS. 6A to 6F are sectional views showing process steps of a conventional method for fabricating a MIM capacitor using the AlOₓ barrier film, which is disclosed in Japanese Unexamined Patent Publication No. 2002-222934.

Referring to FIG. 6A, first, a first interlayer insulating film 61 is formed on a silicon substrate 60, and then a first hole 62 is formed which penetrates the first interlayer insulating film 61. Subsequently, the first hole 62 is filled with tungsten, titanium, titanium nitride, or the like to form a plug 63 of a conductive film (a conductive film plug 63). Then, a second interlayer insulating film 64 is formed on the first interlayer insulating film 61 and the conductive film plug 63. Thereafter, a second hole 65 is formed which penetrates the second interlayer insulating film 64 to reach the conductive film plug 63.

As shown in FIG. 6B, a film 66A of a titanium nitride film or the like as the material for a lower electrode (a lower electrode material film 66A) is formed over the entire surface of the second interlayer insulating film 64 including the inside of the second hole 65.

Next, as shown in FIG. 6C, a CMP (chemical mechanical polishing) or an etch back for the entire surface is performed to remove a portion of the lower electrode material film 66A formed on the top of the second interlayer insulating film 64 and outside the second hole 65. Thus, a lower electrode 66 with a three dimensional structure is formed inside the second hole 65.

Next, as shown in FIG. 6D, by an ALD (Atomic Layer Deposition) method, an AlOₓ film 67 is formed on the lower electrode 66.

FIG. 7 shows a sequence for forming, by an ALD method, the AlOₓ film and a HfOₓ film that will be described later.

Referring to FIG. 7, first, ambient gas (N₂) is introduced into a film formation chamber, and then the silicon substrate (wafer) 60 is heated. Subsequently, TMA (trimethyl aluminum) gas serving as an Al supply source is introduced into the chamber in a series of pulses to chemisorb TMA or its activated species onto the surfaces of the second interlayer insulating film 64 and the lower electrode 66. After interception of TMA gas, purge gas (N₂) is introduced into the chamber in a series of pulses to remove TMA gas remaining within the chamber. The purge gas is then intercepted, and ozone (O₃) gas is introduced into the chamber in a series of pulses. During this introduction, the ozone gas thermally reacts with the TMA or its activated species adsorbed onto the surfaces of the second interlayer insulating film 64 and the lower electrode 66, thereby forming AlO of a single atomic layer. Subsequently, purge gas is introduced again into the chamber in a series of pulses to remove ozone gas remaining within the chamber. The film formation sequence described above is conducted repeatedly multiple times to provide the AlO film 67 with a desired thickness on the lower electrode 66.

Next, as shown in FIG. 6E, by an ALD method, a HfOₓ film 68 is formed on the AlOₓ film 67.

To be more specific, as shown in FIG. 7, first, TEMA-Hf (tetrakis (ethylmethyamino) hafnium) gas serving as a Hf supply source is introduced into the chamber in a series of pulses to chemisorb TEMA-Hf or its activated species onto the surface of the AlO film 67. After interception of TEMA-Hf gas, purge gas is introduced into the chamber in a series of pulses to remove TEMA-Hf gas remaining within the chamber. The purge gas is then intercepted, and ozone gas is introduced into the chamber in a series of pulses. During this introduction, the ozone gas thermally reacts with the TEMA-Hf or its activated species adsorbed onto the surface of the AlOₓ film 67, thereby forming HfOₓ of a single atomic layer. Subsequently, purge gas is introduced again into the chamber in a series of pulses to remove ozone gas remaining within the chamber. The film formation sequence described above is conducted repeatedly multiple times to provide the HfOₓ film 68 with a desired thickness on the AlOₓ film 67.

Then, as shown in FIG. 6F, a film 69 of a titanium nitride film or the like as the material for an upper electrode (an upper electrode material film 69) is formed on the HfOₓ film 68. Thereafter, although not shown, the upper electrode material film 69 is etched in a desired shape to form an upper electrode.

Through the steps shown above, a MIM capacitor having the barrier film of the AlOₓ film 67 is constructed over the silicon substrate 60.

### SUMMARY OF THE INVENTION

If the area occupied by a capacitor increasingly shrinks in the future, it is necessary to reduce the thickness of a capacitor insulating film in order to secure the capacitance. However, use of an AlOₓ barrier film with a lower relative dielectric constant than HfOₓ or ZrOₓ makes it difficult to secure the capacitance by thinning the capacitor insulating film.

For example, in the case where the AlOₓ barrier film has a thickness of 0.5 nm, in order to meet the requirement of Teq (Thickness Equivalent: the thickness in terms of an oxide film)=1.2 nm, the HfOₓ film has to have a thickness of about 3.8 nm (where the relative dielectric constant of AlOₓ is about 9, and the relative dielectric constant of HfOₓ is about 20). In this structure, the thickness of the capacitor insulating film (the HfOₓ film) including the thickness of the AlOₓ barrier film is less than 5 nm, which increases leakage current resulting from a tunnel effect. As is apparent from the above, it is extremely difficult for the MIM capacitor using the AlOₓ barrier film to secure a capacitance of Teq=1.2 nm or smaller.

In view of the foregoing, an object of the present invention is to provide a semiconductor device with a MIM capacitor capable of suppressing both leakage currents resulting from thermal emission of electrons from electrodes and resulting from a tunnel effect and capable of maintaining a high relative dielectric constant, and to provide a method for fabricating such a device.

To attain the above object, the inventors found the fact that as an alternative to the AlOₓ barrier film, to be more specific, as a barrier film made of a material with a high band gap with respect to the electrodes and a high relative dielectric constant, an optimal one is a barrier film made of Hf oxide or Zr oxide containing Al or Si. From this fact, the inventors have devised the following invention.

Specifically, a semiconductor device according to the present invention comprises a capacitor formed by sequentially stacking a lower electrode, a capacitor insulating film, and an upper electrode over a substrate, the capacitor insulating film is made of Hf oxide or Zr oxide, and between the lower electrode and the capacitor insulating film, a first barrier film is formed which is made of Hf oxide or Zr oxide containing at least either of Al and Si.

Preferably, in the semiconductor device according to the present invention, between the upper electrode and the capacitor insulating film, a second barrier film is formed which is made of Hf oxide or Zr oxide containing at least either of Al and Si. Preferably, in this case, the second barrier film is amorphous. Also, preferably, in this case, the Al or Si content of the second barrier film is not less than 1 atm % and less than 25 atm %.

Preferably, in the semiconductor device according to the present invention, the first barrier film is amorphous.

Preferably, in the semiconductor device according to the present invention, the Al or Si content of the first barrier film is not less than 1 atm % and less than 25 atm %.

Preferably, in the semiconductor device according to the present invention, the lower and upper electrodes are each made of at least one of TiN, Ti, Al, W, W, Pt, Ir, and Ru.

A method for fabricating a semiconductor device according to the present invention comprises: the step (a) of forming a capacitor lower electrode over a substrate; the step (b) of forming, on the capacitor lower electrode, a first barrier film made of Hf oxide or Zr oxide containing at least either of Al and Si; the step (c) of forming, on the first barrier film, a capacitor insulating film made of Hf oxide or Zr oxide; and the step (d) of forming a capacitor upper electrode on or over the capacitor insulating film.

Preferably, the method for fabricating a semiconductor device according to the present invention further comprises, between the steps (c) and (d), the step (e) of forming, on the capacitor insulating film, a second barrier film made of Hf oxide or Zr oxide containing at least either of Al and Si. Preferably, in this case, in the step (e), the second barrier film is formed using an ALD method.

Preferably, in the method for fabricating a semiconductor device according to the present invention, in the step (b), the first barrier film is formed using an ALD method.

Preferably, in the method for fabricating a semiconductor device according to the present invention, in the step (c), the capacitor insulating film is formed using an ALD method.

Preferably, the method for fabricating a semiconductor device according to the present invention further comprises, after the step (c), the step (f) of performing plasma oxidation on the capacitor insulating film.

Preferably, in the method for fabricating a semiconductor device according to the present invention, the lower and upper electrodes are each made of at least one of TiN, Ti, Al, W, WN, Pt, Ir, and Ru.

With the present invention, a barrier film made of Hf oxide or Zr oxide containing at least either of Al and Si is provided at the interface between HfOₓ or ZrOₓ constituting a capacitor insulating film and an electrode. With this structure, the band gap between the capacitor insulating film and the electrode can be widened to suppress leakage current resulting from heat emission of electrons from the electrode. Furthermore, the barrier film can also have a high relative dielectric constant equivalent to that of HfOₓ or ZrOₓ, so that the capacitance can be secured and concurrently a physical thickness of a certain extent can be kept. Thereby, leakage current resulting from a tunnel effect can be prevented.

As described above, the present invention relates to semiconductor devices with capacitors and their fabrication methods. In the present invention, the interface between HfOₓ or ZrOₓ constituting a capacitor insulating film and an electrode is provided with a barrier film capable of widening the band gap between the capacitor insulating film and the electrode and suppressing a decrease in relative dielectric constant. This offers the effect of suppressing leakage current resulting from heat emission of electrons from the electrode and the effect of securing the capacitance and concurrently a physical thickness of a certain extent to prevent leakage current resulting from a tunnel effect. Accordingly, the present invention is very useful.

### BRIEF DESCRIPTION OF THE DRAWINGS

FIGS. 1A to 1G are sectional views showing process steps of a method for fabricating a semiconductor device according to a first embodiment of the present invention.

FIG. 2 is a diagram showing a sequence for reactive gas introduction in the step of forming a HfₓAl_{y}O_{z} film by an ALD method in the method for fabricating a semiconductor device according to the first embodiment of the present invention.

FIG. 3 is a graph showing the electrical property of a capacitor with a MIM structure according to the present invention, the capacitor employing a HfOₓ capacitor insulating film and a HfₓAl_{y}O_{z} barrier film between a lower electrode and the capacitor insulating film.

FIG. 4 is a graph showing the correlation between the Al content and the relative dielectric constant of the HfₓAl_{y}O_{z} barrier film in the present invention.

FIG. 5 is a diagram showing a sequence for reactive gas introduction in the step of forming a ZrₓAl_{y}O_{z} film by an ALD method in the method for fabricating a semiconductor device according to a second embodiment of the present invention.

FIGS. 6A to 6F are sectional views showing process steps of a conventional method for fabricating a MIM capacitor.

FIG. 7 is a diagram showing a sequence for forming an AlOₓ film and a HfOₓ film by an ALD method in the conventional method for fabricating a MIM capacitor.

### DETAILED DESCRIPTION OF THE PREFERRED EMBODIMENTS

### First Embodiment

A semiconductor device and its fabrication method according to a first embodiment of the present invention will be described below with reference to the accompanying drawings.

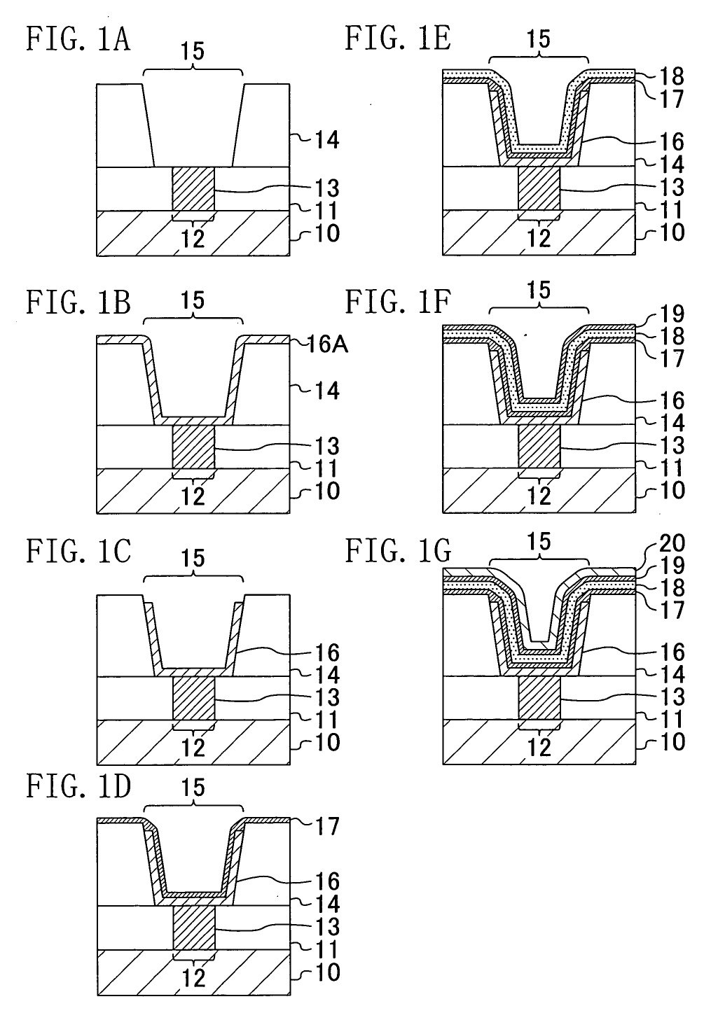

FIGS. 1A to IG are sectional views showing process steps of the semiconductor device fabrication method according to the first embodiment.

Referring to FIG. 1A, first, a first interlayer insulating film 11 with a thickness of, for example, 300 nm is deposited on a semiconductor substrate 10 of silicon or the like. Subsequently, a first hole 12 with a diameter of, for example, 150 nm is formed which penetrates the first interlayer insulating film 11 to reach the semiconductor substrate 10, and then the first hole 12 is filled with a conductor such as tungsten, titanium, or titanium nitride to form a conductive film plug 13. A second interlayer insulating film 14 with a thickness of, for example, 500 nm is deposited on the first interlayer insulating film 11, and then a second hole 15 with a diameter of, for example, 400 nm is formed which penetrates the second interlayer insulating film 14 to reach the conductive film plug 13.

As shown in FIG. 1B, a lower electrode material film 16A of a titanium nitride film or the like is deposited over the entire surface of the second interlayer insulating film 14 including the inside of the second hole 15.

Next, for example, while the second hole 15 is filled with a photoresist (not shown) to protect a portion of the lower electrode material film 16A inside the second hole 15, an etch back for the entire surface is performed to remove a portion of the lower electrode material film 16A formed on the top of the second interlayer insulating film 14 and outside the second hole 15, as shown in FIG. 1C. Thus, a lower electrode 16 of a titanium nitride film or the like is formed inside the second hole 15.

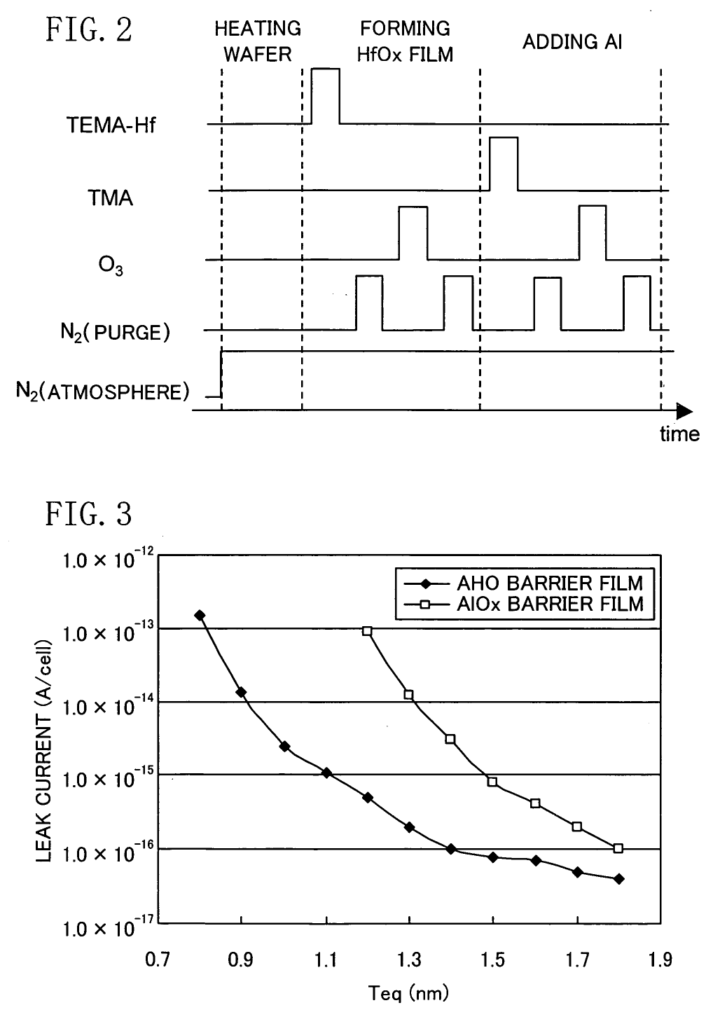

Next, as shown in FIG. 1D, a first barrier film 17 is deposited on the surfaces of the lower electrode 16 and the second interlayer insulating film 14. The first barrier film 17 is made of, for example, amorphous Hf oxide containing Al (Hfₓ AlyOₓ ), and has a thickness of, for example, about 0.5 nm. Formation of the first barrier film 17 is done using an atomic layer deposition (ALD) method or the like. In the film formation by the ALD method, reactive gas is introduced into a chamber (a reaction chamber) intermittently in a series of pulses. FIG. 2 shows a sequence for reactive gas introduction in the step of forming a HfₓAl_{y}O_{z} film by an ALD method according to the first embodiment.

To be more specific, as shown in FIG. 2, first, ambient gas (for example, nitrogen (N₂) gas) is introduced into the chamber, and then the semiconductor substrate 10 is heated to, for example, about 200 to 400° C. During this heating, the gas pressure within the chamber is set at about 100 Pa. Instead of nitrogen gas, inert gas such as argon can be used as ambient gas. Subsequently, for example, TEMA-Hf (tetrakis (ethylmethyamino) hafnium) gas serving as a Hf supply source is introduced into the chamber in a series of pulses to chemisorb TEMA-Hf or its activated species onto the surfaces of the second interlayer insulating film 14 and the lower electrode 16. After interception of TEMA-Hf gas, purge gas is introduced into the chamber in a series of pulses to remove TEMA-Hf gas remaining within the chamber. As the purge gas introduced, use can be made of, for example, nitrogen gas, argon gas, or helium gas. The purge gas is then intercepted, and ozone (O₃) gas is introduced into the chamber in a series of pulses. During this introduction, the ozone gas thermally reacts with the TEMA-Hf or its activated species adsorbed onto the surfaces of the second interlayer insulating film 14 and the lower electrode 16, thereby forming HfOₓ of a single atomic layer. Subsequently, purge gas is introduced again into the chamber in a series of pulses to remove ozone gas remaining within the chamber.

In the first embodiment, the HfOₓ film formation sequence described above is conducted repeatedly, for example, two or three times to produce a HfOₓ film of, for example, two or three atomic layers. After this formation, a sequence of Al addition to the HfOₓ film that will be described below will be conducted.

Specifically, after formation of the HfOₓ film, as shown in FIG. 2, TMA (trimethyl aluminum) gas serving as an Al supply source is introduced into the chamber in a series of pulses to chemisorb TMA or its activated species onto the surface of the HfOₓ film. After interception of TMA gas, purge gas (for example, nitrogen gas) is introduced into the chamber in a series of pulses to remove TMA gas remaining within the chamber. The purge gas is then intercepted, and ozone gas is introduced into the chamber in a series of pulses. During this introduction, thermal reaction occurs among the ozone gas, the TMA or its activated species adsorbed onto the surface of the HfOₓ film, and the underlying HfOₓ, thereby forming an amorphous HfₓAl_{y}O_{z} film. Subsequently, purge gas is introduced again into the chamber in a series of pulses to remove ozone gas remaining within the chamber.

In the first embodiment, the HfOₓ film formation sequence shown above is conducted two or three times, and the sequence of Al addition to HfOₓ shown above is conducted once, thereby forming the amorphous HfₓAl_{y}O_{z} film. The HfₓAl_{y}O_{z} film formation process thus conducted is carried out, for example, twice to provide a first barrier film 17 made of an amorphous HfₓAl_{y}O_{z} film with a thickness of, for example, about 0.5 nm. In this process, the first barrier film 17 has an Al content of, for example, about 15% and a relative dielectric constant of about 15. Note that in the first embodiment, the ratio in the number of times between the HfOₓ film formation sequence and the sequence of Al addition to HfOₓ can be modified to arbitrarily set the Al content of the first barrier film 17.

As shown in FIG. 1E, by an ALD method or the like, a capacitor insulating film 18 of, for example, HfOₓ is formed on the surface of the first barrier film 17. Specifically, the HfOₓ film formation sequence in FIG. 2 is conducted repeatedly, for example, about thirty times to form the capacitor insulating film 18 made of a HfOₓ film with a thickness of, for example, about 4.8 nm.

Next, as shown in FIG. iF, a second barrier film 19 is deposited on the surface of the capacitor insulating film 18. In the first embodiment, like the first barrier film 17, the second barrier film 19 is made of, for example, an amorphous Hf oxide containing Al (HfₓAl_{y}O_{z}) and has a thickness of, for example, about 0.5 nm. The second barrier film 19 is formed, for example, by the same formation procedure as the first barrier film 17 shown in FIG. 2.

In the first embodiment, a stacked product of the 0.5 nm-thick HfₓAl_{y}O_{z} film as the first barrier film 17, the 4.8 nm-thick HfOₓ film as the capacitor insulating film 18, and the 0.5 nm-thick HfₓAl_{y}O_{z} film as the second barrier film 19 can satisfy the requirement of Teq =1.2 nm.

Subsequently, the first barrier film 17, the capacitor insulating film 18, and the second barrier film 19 are subjected to plasma oxidation to supply oxygen to oxygen vacancies in the first barrier film 17, the capacitor insulating film 18, and the second barrier film 19.

As shown in FIG. 1G, an upper electrode material film 20 of a titanium nitride film or the like with a thickness of about 50 nm is formed on the second barrier film 19. Thereafter, although not shown, the upper electrode material film 20 is etched in a desired shape to form an upper electrode.

Through the steps shown above, over the semiconductor substrate 10, a MIM capacitor according to the first embodiment is constructed which has the barrier films each made of a HfₓAl_{y}O_{z} film.

In the first embodiment, the first barrier film 17 of the HfₓAl_{y}O_{z} film, that is, Hf oxide containing Al is provided at the interface between the lower electrode 16 and HfOₓ constituting the capacitor insulating film 18, and the second barrier film 19 made of the HfₓAl_{y}O_{z} film (Hf oxide containing Al) is provided at the interface between the upper electrode and HfOₓ constituting the capacitor insulating film 18. With this structure, the band gap between the capacitor insulating film 18 and each of the electrodes can be widened to suppress leakage current resulting from heat emission of electrons from the electrodes. Furthermore, the barrier films 17 and 19 can also have high relative dielectric constants equivalent to that of HfOₓ, so that the capacitance can be secured and concurrently a physical thickness of a certain extent can be kept. Thereby, leakage current resulting from a tunnel effect can be prevented.

FIG. 3 shows the electrical property of the capacitor with the MIM structure according to the present invention, which is compared to the electrical property of the conventional capacitor with the MIM structure. The capacitor of the present invention employs a HfOₓ capacitor insulating film and a HfₓAl_{y}O_{z} barrier film (an AHO barrier film) provided between the lower electrode and the capacitor insulating film, while the conventional capacitor employs a HfOₓ capacitor insulating film and an AlOₓ barrier film provided between the lower electrode and the capacitor insulating film. FIG. 3 plots Teq (the thickness in terms of an oxide film) of the capacitor in abscissa and leakage current per memory cell in ordinate.

As can be seen from FIG. 3, for the conventional MIM-structure capacitor using the AlOₓ barrier film, when Teq is about 1.4 nm or smaller, leakage current significantly increases. Therefore, the requirement of Teq=1.2 nm cannot be satisfied.

On the other hand, for the MIM-structure capacitor of the present invention using the HfₓAl_{y}O_{z} barrier film, an increase of leakage current is suppressed in the range of Teq of about 1.0 nm or more. Therefore, the requirement of Teq=1.2 nm can be satisfied sufficiently. That is to say, the Hfₓ Al_{y}O_{z} barrier film in the present invention has a band gap sufficient for suppression of leakage current resulting from heat emission of electrons from the electrodes.

Moreover, in the first embodiment, since the first barrier film 17 as an underlying layer of the capacitor insulating film 18 is amorphous, the capacitor insulating film 18 can be formed in an amorphous or amorphouslike state. Therefore, leakage current of the capacitor can be further reduced.

Furthermore, in the first embodiment, since formation of the first and second barrier films 17 and 19 is done using an ALD method, an amorphous HfₓAl_{y}O_{z} film serving as the first barrier film 17 can be formed certainly on the surface of the lower electrode 16 and an amorphous HfₓAl_{y}O_{z} film serving as the second barrier film 19 can be formed certainly on the surface of the capacitor insulating film 18. Therefore, the above effects can be exerted reliably.

In the first embodiment, the composition of the HfₓAl_{y}O_{z} film employed as the first and second barrier films 17 and 19 preferably satisfies x+y+z=1, 0.115<x≦0.32, 0.01≦y<0.25, and 0.635≦z≦0.67. That is to say, the Al content of the first barrier film 17 or the second barrier film 19 is preferably not less than 1 atm % and less than 25 atm %. With such content, a decrease in relative dielectric constant of the respective barrier films can be prevented while the band gaps of the barrier films with respect to the electrodes can be made higher than that of HfOₓ.

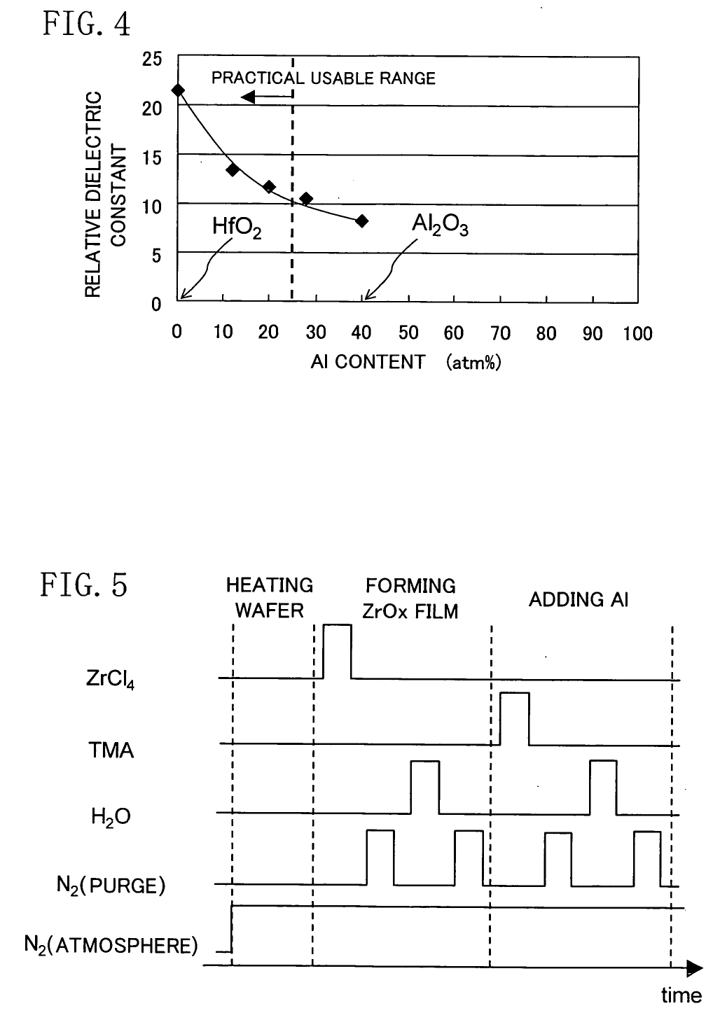

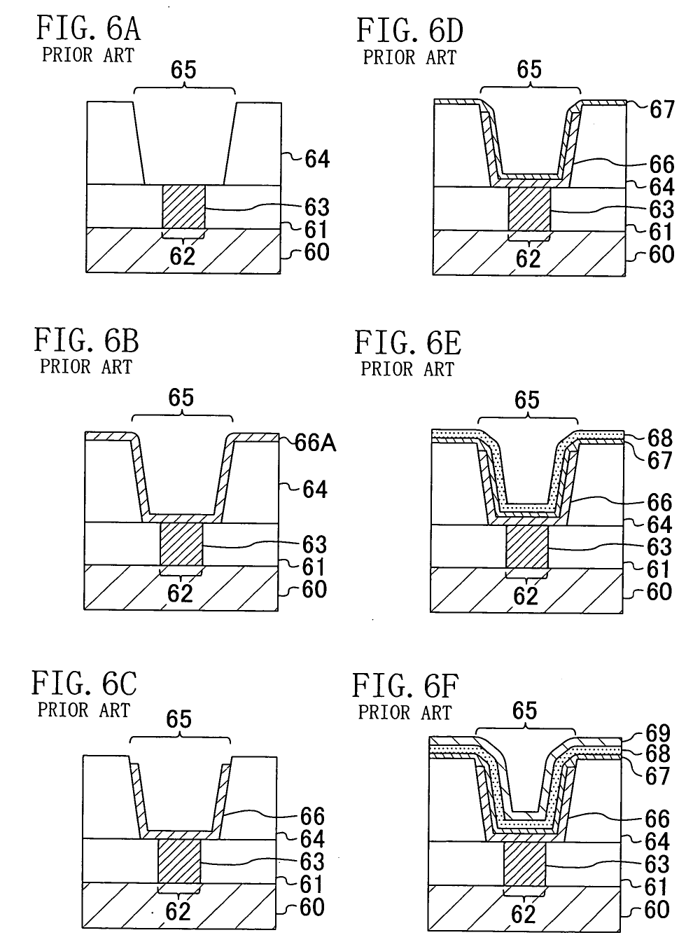

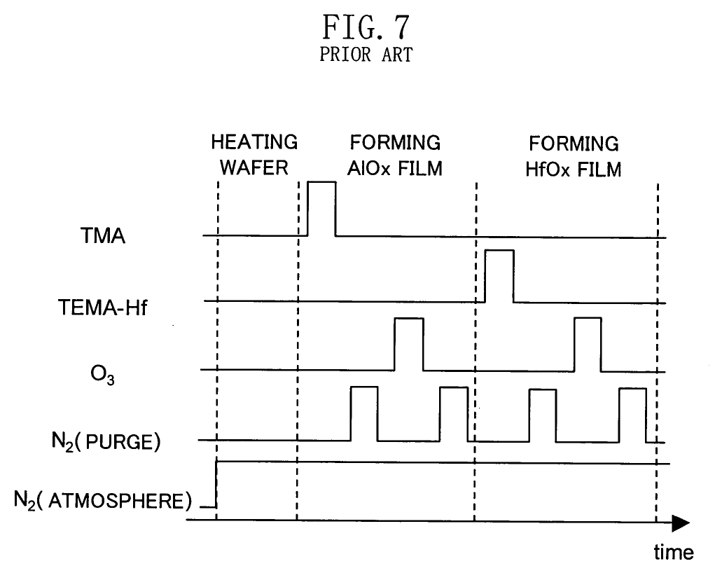

FIG. 4 shows the correlation between the Al content and the relative dielectric constant of the HfₓAl_{y}O_{z} barrier film in the present invention. FIG. 4 plots the Al content of the HfₓAl_{y}O_{z} barrier film in abscissa and the relative dielectric constant thereof in ordinate. As can be seen from FIG. 4, when the Al content is less than 25 atm %, the HfₓAl_{y}O_{z} barrier film can have the relative dielectric constant as practical as 12 to 13 or more.

In the first embodiment, instead of the HfₓAl_{y}O_{z} film, a HfₓSi_{y}O_{z} film (Hf oxide containing Si) or Hf oxide containing both Al and Si may be employed as the first barrier film 17 or the second barrier film 19. In the case of employing a HfₓSi_{y}O_{z} film, its composition preferably satisfies x+y+z=1, 0.115<x≦0.32, 0.01≦y≦0.25, and 0.635≦z≦0.67. That is to say, the Si content of the first barrier film 17 or the second barrier film 19 is preferably not less than 1 atm % and less than 25 atm %. With such content, a decrease in relative dielectric constant of the respective barrier films can be prevented while the band gaps of the barrier films with respect to the electrodes can be made higher than that of HfOₓ.

In the first embodiment, the first and second barrier films 17 and 19 may be made of different materials. Either of the first and second barrier films 17 and 19 may not be provided.

In the first embodiment, the Al or Si content of the HfOₓ film serving as the capacitor insulating film 18 is preferably less than 1 atm % from the viewpoint of preventing a decrease in relative dielectric constant. Note that as the capacitor insulating film 18, a ZrOₓ film may be employed instead of a HfOₓ film.

The first embodiment is designed for a MIM capacitor produced in a recess provided in an insulating film over a substrate. Alternatively, the first embodiment may be designed for another type of MIM capacitor.

In the first embodiment, a titanium nitride (TiN) film is employed for the lower electrode 16 and the upper electrode. The material for the electrodes is not limited to this, and the lower electrode 16 and the upper electrode may be made of at least one of TiN, Ti, Al, W, WN, Pt, Ir, and Ru. The lower electrode 16 and the upper electrode may be made of different materials.

In the first embodiment, when the first barrier film 17, the capacitor insulating film 18, and the second barrier film 19 are each formed using an ALD method, a single atom layer is formed at a time. Instead of this, two or three atom layers may be formed at a time.

### Second Embodiment

A semiconductor device and its fabrication method according to a second embodiment of the present invention will be described below with reference to the accompanying drawings.

The second embodiment greatly differs from the first embodiment in that instead of HfOₓ, ZrOₓ is employed for a capacitor insulating film and instead of a HfₓAl_{y}O_{z} film, a ZrₓAl_{y}O_{z} is employed for a barrier film.

In the semiconductor device fabrication method according to the second embodiment, first, the same steps as those of the first embodiment shown in FIGS. 1A to 1C, that is, the steps up to the step of forming the lower electrode 16 of the capacitor over the semiconductor substrate 10 are carried out.

Next, as shown in FIG. 1D, a first barrier film 17 is deposited on the surfaces of the lower electrode 16 and the second interlayer insulating film 14. In the second embodiment, the first barrier film 17 is made of, for example, amorphous Zr oxide containing Al (ZrₓAl_{y}O_{z}) and has a thickness of, for example, about 0.5 nm. Formation of the first barrier film 17 is done using an atomic layer deposition (ALD) method or the like. In the film formation by the ALD method, reactive gas is introduced into a chamber (a reaction chamber) intermittently in a series of pulses. FIG. 5 shows a sequence for reactive gas introduction in the step of forming a ZrₓAl_{y}O_{z} film by an ALD method according to the second embodiment.

To be more specific, as shown in FIG. 5, first, ambient gas (for example, nitrogen gas) is introduced into the chamber, and then the semiconductor substrate 10 is heated to, for example, about 200 to 400° C. During this heating, the gas pressure within the chamber is set at about 100 Pa. Instead of nitrogen gas, inert gas such as argon can be used as ambient gas. Subsequently, for example, ZrCl₄ (zirconium tetrachloride) gas serving as a Zr supply source is introduced into the chamber in a series of pulses to chemisorb ZrCl₄ or its activated species onto the surfaces of the second interlayer insulating film 14 and the lower electrode 16. After interception of ZrCl₄ gas, purge gas is introduced into the chamber in a series of pulses to remove ZrCl₄ gas remaining within the chamber. As the purge gas introduced, use can be made of, for example, nitrogen gas, argon gas, or helium gas. The purge gas is then intercepted, and H₂O (vapor) is introduced into the chamber in a series of pulses. During this introduction, the H₂O thermally reacts with the ZrCl₄ or its activated species adsorbed onto the surfaces of the second interlayer insulating film 14 and the lower electrode 16, thereby forming ZrOₓ of a single atomic layer. Subsequently, purge gas is introduced again into the chamber in a series of pulses to remove H₂O remaining within the chamber.

In the second embodiment, the ZrOₓ film formation sequence described above is conducted repeatedly, for example, two or three times to produce a ZrOₓ film of, for example, two or three atomic layers. After this formation, a sequence of Al addition to the ZrOₓ film that will be described below will be conducted.

Specifically, after formation of the ZrOₓ film, as shown in FIG. 5, TMA (trimethyl aluminum) gas serving as an Al supply source is introduced into the chamber in a series of pulses to chemisorb TMA or its activated species onto the surface of the ZrOx film. After interception of TMA gas, purge gas (for example, nitrogen gas) is introduced into the chamber in a series of pulses to remove TMA gas remaining within the chamber. The purge gas is then intercepted, and H₂O (vapor) is introduced into the chamber in a series of pulses. During this introduction, thermal reaction occurs among the H₂O, the TMA or its activated species adsorbed onto the surface of the ZrOₓ film, and the underlying ZrOₓ, thereby forming an amorphous Zrₓ Al_{y}O_{z} film. Subsequently, purge gas is introduced again into the chamber in a series of pulses to remove H₂O remaining within the chamber.

In the second embodiment, the ZrOₓ film formation sequence shown above is conducted two or three times, and the sequence of Al addition to ZrOₓ shown above is conducted once, thereby forming the amorphous ZrₓAl_{y}O_{z} film. The ZrₓAl_{y}O_{z} film formation process thus conducted is carried out, for example, twice to provide the first barrier film 17 made of an amorphous ZrₓAl_{y}O_{z} film with a thickness of, for example, about 0.5 nm. In this process, the first barrier film 17 has an Al content of, for example, about 15% and a relative dielectric constant of about 15. Note that in the second embodiment, the ratio in the number of times between the ZrOₓ film formation sequence and the sequence of Al addition to ZrOₓ can be modified to arbitrarily set the Al content of the first barrier film 17.

As shown in FIG. 1E, by an ALD method or the like, a capacitor insulating film 18 of, for example, ZrOₓ is formed on the surface of the first barrier film 17. Specifically, the ZrOₓ film formation sequence in FIG. 5 is conducted repeatedly, for example, about thirty times to form the capacitor insulating film 18 made of a ZrOₓ film with a thickness of, for example, about 4.8 nm.

Next, as shown in FIG. 1F, a second barrier film 19 is deposited on the surface of the capacitor insulating film 18. In the second embodiment, like the first barrier film 17, the second barrier film 19 is made of, for example, an amorphous Zr oxide containing Al (ZrₓAl_{y}O_{z} ) and has a thickness of, for example, about 0.5 nm. The second barrier film 19 is formed, for example, by the same formation procedure as the first barrier film 17 shown in FIG. 5.

In the second embodiment, a stacked product of the 0.5 nm-thick ZrₓAl_{y}O_{z} film as the first barrier film 17, the 4.8 nm-thick ZrOₓ film as the capacitor insulating film 18, and the 0.5 nm-thick ZrₓAl_{y}O_{z} film as the second barrier film 19 can satisfy the requirement of Teq=1.2 nm.

Subsequently, the first barrier film 17, the capacitor insulating film 18, and the second barrier film 19 are subjected to plasma oxidation to supply oxygen to oxygen vacancies in the first barrier film 17, the capacitor insulating film 18, and the second barrier film 19.

As shown in FIG. 1G, an upper electrode material film 20 of a titanium nitride film or the like with a thickness of about 50 nm is formed on the second barrier film 19. Thereafter, although not shown, the upper electrode material film 20 is etched in a desired shape to form an upper electrode.

Through the steps shown above, over the semiconductor substrate 10, a MIM capacitor according to the second embodiment is constructed which has the barrier films each made of a ZrₓAl_{y}O_{z} film.

In the second embodiment, the first barrier film 17 of the ZrₓAl_{y}O_{z} film, that is, Zr oxide containing Al is provided at the interface between the lower electrode 16 and ZrOₓ constituting the capacitor insulating film 18, and the second barrier film 19 made of the ZrₓAl_{y}O_{z} film (Zr oxide containing Al) is provided at the interface between the upper electrode and ZrOₓ constituting the capacitor insulating film 18. With this structure, the band gap between the capacitor insulating film 18 and each of the electrodes can be widened to suppress leakage current resulting from heat emission of electrons from the electrodes. Furthermore, the barrier films 17 and 19 can also have high relative dielectric constants equivalent to that of ZrOₓ, so that the capacitance can be secured and concurrently a physical thickness of a certain extent can be kept. Thereby, leakage current resulting from a tunnel effect can be prevented.

Moreover, in the second embodiment, since the first barrier film 17 as an underlying layer of the capacitor insulating film 18 is amorphous, the capacitor insulating film 18 can be formed in an amorphous or amorphouslike state. Therefore, leakage current of the capacitor can be further reduced.

Furthermore, in the second embodiment, since formation of the first and second barrier films 17 and 19 is done using an ALD method, an amorphous ZrₓAl_{y}O_{z} film serving as the first barrier film 17 can be formed certainly on the surface of the lower electrode 16 and an amorphous ZrₓAl_{y}O_{z} film serving as the second barrier film 19 can be formed certainly on the surface of the capacitor insulating film 18. Therefore, the above effects can be exerted reliably.

In the second embodiment, the composition of the ZrₓAl_{y}O_{z} film employed as the first and second barrier films 17 and 19 preferably satisfies x+y+z=, 0.115<x≦0.32, 0.01≦y<0.25, and 0.635≦z≦0.67. That is to say, the Al content of the first barrier film 17 or the second barrier film 19 is preferably not less than 1 atm % and less than 25 atm %. With such content, a decrease in relative dielectric constant of the respective barrier films can be prevented while the band gaps of the barrier films with respect to the electrodes can be made higher than that of ZrOₓ.

In the second embodiment, instead of the ZrₓAl_{y}O_{z} film, a ZrₓSi_{y}O_{z} film (Zr oxide containing Si) or Zr oxide containing both Al and Si can be employed as the first barrier film 17 or the second barrier film 19. In the case of employing a ZrₓSi_{y}O_{z} film, its composition preferably satisfies x+y+z=1, 0.115<x≦0.32, 0.01≦≦y<0.25, and 0.635≦z≦0.67. That is to say, the Si content of the first barrier film 17 or the second barrier film 19 is preferably not less than 1 atm % and less than 25 atm %. With such content, a decrease in relative dielectric constant of the respective barrier films can be prevented while the band gaps of the barrier films with respect to the electrodes can be made higher than that of ZrOₓ.

In the second embodiment, the first and second barrier films 17 and 19 may be made of different materials. Either of the first and second barrier films 17 and 19 may not be provided.

In the second embodiment, the Al or Si content of the ZrOₓ film serving as the capacitor insulating film 18 is preferably less than 1 atm % from the viewpoint of preventing a decrease in relative dielectric constant. Note that as the capacitor insulating film 18, a HfOₓ film may be employed instead of a ZrOₓ film.

The second embodiment is designed for a MIM capacitor produced in a recess provided in an insulating film over a substrate. Alternatively, the second embodiment may be designed for another type of MIM capacitor.

In the second embodiment, a titanium nitride (TiN) film is employed for the lower electrode 16 and the upper electrode. The material for the electrodes is not limited to this, and the lower electrode 16 and the upper electrode may be made of at least one of TiN, Ti, Al, W, WN, Pt, Ir, and Ru. The lower electrode 16 and the upper electrode may be made of different materials.

In the second embodiment, when the first barrier film 17, the capacitor insulating film 18, and the second barrier film 19 are each formed by an ALD method, a single atom layer is formed at a time. Instead of this, two or three atom layers may be formed at a time.

What is claimed is:

1. A semiconductor device,
wherein the device comprises a capacitor formed by sequentially stacking a lower electrode, a capacitor insulating film, and an upper electrode over a substrate,
the capacitor insulating film is made of Hf oxide or Zr oxide, and
between the lower electrode and the capacitor insulating film, a first barrier film is formed which is made of Hf oxide or Zr oxide containing at least either of Al and Si.

2. The device of claim 1,
wherein between the upper electrode and the capacitor insulating film, a second barrier film is formed which is made of Hf oxide or Zr oxide containing at least either of Al and Si.

3. The device of claim 2,
wherein the second barrier film is anorphous.

4. The device of claim 2,
wherein the Al or Si content of the second barrier film is not less than 1 atm % and less than 25 atm %.

5. The device of claim 1,
wherein the first barrier film is amorphous.

6. The device of claim 1,
wherein the Al or Si content of the first barrier film is not less than 1 atm % and less than 25 atm %.

7. The device of claim 1,
wherein the lower and upper electrodes are each made of at least one of TiN, Ti, Al, W, WN, Pt, Ir, and Ru.

8. A method for fabricating a semiconductor device, comprising:
the step (a) of forming a capacitor lower electrode over a substrate;
the step (b) of forming, on the capacitor lower electrode, a first barrier film made of Hf oxide or Zr oxide containing at least either of Al and Si;
the step (c) of forming, on the first barrier film, a capacitor insulating film made of Hf oxide or Zr oxide; and
the step (d) of forming a capacitor upper electrode on or over the capacitor insulating film.

9. The method of claim 8, further comprising, between the steps (c) and (d), the step (e) of forming, on the capacitor insulating film, a second barrier film made of Hf oxide or Zr oxide containing at least either of Al and Si.

10. The method of claim 9,
wherein in the step (e), the second barrier film is formed using an ALD method.

11. The method of claim 8,
wherein in the step (b), the first barrier film is formed using an ALD method.

12. The method of claim 8,
wherein in the step (c), the capacitor insulating film is formed using an ALD method.

13. The method of claim 8, further comprising, after the step (c), the step (f) of performing plasma oxidation on the capacitor insulating film.

14. The method of claim 8,
wherein the lower and upper electrodes are each made of at least one of TiN, Ti, Al, W, WN, Pt, Ir, and Ru.
